(19) United States
(12) Patent Application Publication
(10) Pub. No.: US 2026/0163361 A1
(43) Pub. Date: Jun. 11, 2026

(54) ELECTROSTATIC DISCHARGE CIRCUIT, ARRAY SUBSTRATE AND DISPLAY APPARATUS

(71) Applicant: BOE Technology Group Co., Ltd., Beijing (CN)

(72) Inventors: Shunhang ZHANG, Beijing (CN); Dongni LIU, Beijing (CN); Zhenyu ZHANG, Beijing (CN); Yunsik IM, Beijing (CN); Minghua XUAN, Beijing (CN); Zhen ZHANG, Beijing (CN); Peirou LI, Beijing (CN); Zhuo LI, Beijing (CN)

(21) Appl. No.: 18/709,152

(22) PCT Filed: Dec. 8, 2022
(86) PCT No.: PCT/CN2022/137670

§ 371 Date: May 10, 2024

(51) Int. Cl. H02H 9/00; H02H 9/04; H10H 29/49

(52) U.S. Cl. CPC H02H 9/005; H02H 9/04; H10H 29/49

(57) ABSTRACT

Disclosed are an electrostatic discharge circuit, an array substrate, and a display apparatus. The electrostatic discharge circuit includes a first static electricity conducting component and a second static electricity conducting component each coupled between a first signal terminal and a second signal terminal. The first static electricity conducting component and the second static electricity conducting component both can, based on that an absolute value of a first voltage difference between the first signal terminal and the second signal terminal is less than a first threshold voltage, disconnect the first and second signal terminals. Based on an absolute value of a second voltage difference between the first signal terminal and the second signal terminal is greater than a second threshold voltage, the potential of the first signal terminal can be caused to increase or decrease and the potential of the second signal terminal can be caused to decrease or increase.

### CROSS REFERENCE TO RELATED APPLICATIONS

This application is a national phase entry under 35 U.S.C. § 371 of International Application No. PCT/CN2022/137670, filed on Dec. 8, 2022, the entire content of which is incorporated herein by reference.

### TECHNICAL FIELD

The disclosure relates to the field of display technologies, in particular to an electrostatic discharge circuit, an array substrate and a display apparatus.

### BACKGROUND

A display apparatus generally includes a plurality of pixels. The image display is realized by controlling the brightness corresponding to each pixel. The display apparatus using Light-Emitting Diodes (LEDs) is formed by arranging the LEDs in an array, and is theoretically capable of adapting to various screen sizes.

### SUMMARY

Embodiments of the disclosure provide an electrostatic discharge circuit, including: a first static electricity conducting component and a second static electricity conducting component each coupled between a first signal terminal and a second signal terminal. The first static electricity conducting component is configured to: based on that an absolute value of a first voltage difference between the first signal terminal and the second signal terminal is less than a first threshold voltage, disconnect the first signal terminal from the second signal terminal; and based on that a potential of the first signal terminal is less than a potential of the second signal terminal, and an absolute value of a second voltage difference between the first signal terminal and the second signal terminal is greater than a second threshold voltage, rise the potential of the first signal terminal and lower the potential of the second signal terminal; where the second threshold voltage is greater than or equal to the first threshold voltage. The second static electricity conducting component is configured to: based on that the absolute value of the first voltage difference between the first signal terminal and the second signal terminal is less than the first threshold voltage, disconnect the first signal terminal from the second signal terminal; and based on that the potential of the first signal terminal is greater than the potential of the second signal terminal, and the absolute value of the second voltage difference between the first signal terminal and the second signal terminal is greater than the second threshold voltage, lower the potential of the first signal terminal and rise the potential of the second signal terminal.

In some embodiments, the first static electricity conducting component includes: M first transistors connected in series in sequence. In the M first transistors, a second electrode of a first transistor at a first position is coupled to the first signal terminal, a first electrode of a first transistor at an m-th position is coupled to a second electrode of a first transistor at an (m+1)-th position, and a first electrode of a first transistor at a M-th position is coupled to the second signal terminal; where 1≤m≤M, and m and M are integers.

In some embodiments, all the first transistors in the first static electricity conducting component are P-type transistors, and a second electrode and a gate of the first transistor are coupled to each other; and M satisfies a following formula: (M−1)*|Vth1|>ΔV1; where Vth1 indicates a rated threshold voltage of one first transistor, and ΔV1 indicates a maximum value of the absolute value of the first voltage difference.

In some embodiments, all first transistors in the first static electricity conducting component are N-type transistors, and a first electrode and a gate of the first transistor are coupled to each other; and M satisfies a following formula: (M−1)*|Vth1|>ΔV1; where Vth1 indicates a rated threshold voltage of one first transistor, and ΔV1 indicates a maximum value of the absolute value of the first voltage difference.

In some embodiments, the second static electricity conducting component includes: N second transistors connected in series in sequence. In the N second transistors, a first electrode of a second transistor at a first position is coupled to the first signal terminal, a second electrode of a second transistor at a n-th position is coupled to a first electrode of a second transistor at a (n+1)-th position, a second electrode of a second transistor at a N-th position is coupled to the second signal terminal; where 1≤n≤N, and n and N are integers.

In some embodiments, all second transistors in the second static electricity conducting component are P-type transistors, and a second electrode and a gate of the second transistor are coupled with each other; and N satisfies a following formula: (N−1)*|Vth2|>ΔV1; where Vth2 indicates a rated threshold voltage of one second transistor, and ΔV1 indicates a maximum value of the absolute value of the first voltage difference.

In some embodiments, all second transistors in the second static electricity conducting component are N-type transistors, and a first electrode and a gate of the second transistor are coupled with each other; and N satisfies a following formula: (N−1)*|Vth2|>ΔV1; where Vth2 indicates a rated threshold voltage of one second transistor and, and ΔV1 indicates a maximum value of the absolute value of the first voltage difference.

Embodiments of the disclosure also provide an array substrate including: a base substrate; a plurality of pixels on the base substrate, at least one of the plurality of pixels including a pixel circuit; a plurality of signal lines on the base substrate, the pixel circuit of the at least one of the plurality of pixels being coupled to at least one of the plurality of signal lines; and a plurality of electrostatic discharge circuits provided by the embodiments of the disclosure on the base substrate. A first signal terminal of any one of the plurality of electrostatic discharge circuits is coupled to one of the plurality of signal lines, and a second signal terminal is coupled to another one of the plurality of signal lines; and two signal lines connected with the same electrostatic discharge circuit are arranged adjacent to each other.

In some embodiments, the array substrate includes a display region and a peripheral region; the plurality of pixels and the plurality of signal lines are located in the display region; and the plurality of electrostatic discharge circuits are located in the peripheral region.

In some embodiments, the peripheral region further includes: at least one electrostatic transmission line and at least one ground terminal. At least one endpoint of the at least one electrostatic transmission line is coupled to at least one of the at least one ground terminal; and the at least one electrostatic transmission line is coupled to at least one of the plurality of signal lines via at least one of the plurality of electrostatic discharge circuits.

In some embodiments, the at least one electrostatic transmission line is arranged around the plurality of pixels.

In some embodiments, the peripheral region further includes: a plurality of signal transmission terminals at first ends of the plurality of signal lines. The first end of each of the plurality of signal lines is coupled to at least one of the plurality of signal transmission terminals; and the at least one ground terminal is located at at least one side of the plurality of signal transmission terminals, and the at least one electrostatic transmission line extends from a side of the plurality of signal transmission terminals to the other side of the plurality of signal transmission terminals.

In some embodiments, the plurality of electrostatic discharge circuits are located between a region where the plurality of signal transmission terminals are located and a region where the plurality of signal lines are located.

In some embodiments, the signal lines include data signal lines. Pixel circuits in one column of pixels are coupled to at least one data signal line of the plurality of signal lines; and the first voltage difference is a voltage difference between a data voltage corresponding to a maximum grayscale and a data voltage corresponding to a minimum grayscale loaded on the data signal line.

Embodiments of the disclosure also provide a display apparatus, including a plurality of array substrates spliced together as described above.

### BRIEF DESCRIPTION OF FIGURES

FIG. 1 shows a schematic structural diagram of an electrostatic discharge circuit provided by embodiments of the disclosure.

FIG. 2 shows a detailed schematic structural diagram of an electrostatic discharge circuit provided by embodiments of the disclosure.

FIG. 3A shows a schematic diagram of a simulation provided by embodiments of the disclosure.

FIG. 3B shows another schematic diagram of a simulation provided by embodiments of the disclosure.

FIG. 3C shows yet another schematic diagram of a simulation provided by embodiments of the disclosure.

FIG. 4 shows a schematic diagram of a layout structure of an electrostatic discharge circuit provided by embodiments of the disclosure.

FIG. 5A shows a sectional view of some structures of the electrostatic discharge circuit along the CC′ direction in FIG. 4.

FIG. 5B shows a sectional view of some structures of the electrostatic discharge circuit along the DD′ direction in FIG. 4.

FIG. 6 shows another detailed schematic structural diagram of an electrostatic discharge circuit provided by embodiments of the disclosure.

FIG. 7 shows a schematic diagram of a layout structure of an electrostatic discharge circuit provided by embodiments of the disclosure.

FIG. 8A shows a sectional view of some structures of the electrostatic discharge circuit along the CC′ direction in FIG. 7.

FIG. 8B shows a sectional view of some structures of the electrostatic discharge circuit along the DD′ direction in FIG. 7.

FIG. 9 shows a schematic structural diagram of an array substrate provided by embodiments of the disclosure.

FIG. 10 is another schematic structural diagram of an array substrate provided by embodiments of the disclosure.

FIG. 11 is yet another schematic structural diagram of an array substrate provided by embodiments of the disclosure.

### DETAILED DESCRIPTION

In order to make the objectives, technical solutions and advantages of the embodiments of the disclosure clearer, the technical solutions of the embodiments of the disclosure will be described clearly and completely in the following in conjunction with the drawings of the embodiments of the disclosure. Obviously, the described embodiments are a part of the embodiments of the disclosure, and not all of the embodiments. In addition, the embodiments and the features in the embodiments of the disclosure can be combined with each other without conflict. Based on the described embodiments of the disclosure, all other embodiments obtained by a person of ordinary skill in the art without inventive efforts are within the protection scope of the disclosure.

Unless otherwise defined, the technical or scientific terms used in the disclosure shall have the ordinary meaning understood by a person of ordinary skill in the field to which the disclosure belongs. The terms “first”, “second”, and the like as used in the disclosure do not indicate any order, number, or significance, but are only used to distinguish different components. The words “including” or “comprising” and the like are intended to mean that the component or object preceded by the word encompasses the components or objects listed after the word and their equivalents, and does not exclude other components or objects. The words “connected” or “coupled” and the like are not limited to physical or mechanical connections, but may include electrical connections, whether direct or indirect.

It should be noted that the dimensions and shapes of the figures in the drawings do not reflect true proportions, but are intended to be illustrative of the invention only. And throughout the same or similar labeling denotes the same or similar elements or elements having the same or similar function.

Mini LEDs refer to inorganic light-emitting diodes with a chip size between 100 μm-300 μm, and Micro-LEDs refer to inorganic light-emitting diodes with a chip size below 100 μm. Miniature light-emitting diodes (including Mini-LEDs and Micro-LEDs) can be used to realize self-Illumination display apparatuses, which have the advantages of high brightness, high contrast, fast response, and low power consumption, and thus display technologies based on miniature light-emitting diodes have been more and more widely used in the display field. Specifically, miniaturization of the display panel in matrix with the thin-film can be realized by integrating a high-density light-emitting device array on a base substrate. With the rapid development of display technology, the splicing display apparatus formed based on miniature light-emitting diodes is more and more widely used in large display scenarios such as command and control centers, business centers, high-end conferences, and home theaters, and has a wide application prospect.

Typically, in order to maximize the effective display area of the display apparatus, an integrated circuit (IC) that provides signals to signal wires on the display surface of the base substrate can be provided on the non-display surface of the base substrate, specifically, the signal wire is in a bonding connection with IC through a structure such as a connection wire and/or a flexible printed circuit (FPC) on a side surface of the base substrate. As a large amount of static electricity will inevitably be generated during the preparation of the array substrate, the static electricity will be transmitted to the display surface of the base substrate through the electrical components or lines, and if the static electricity reaches thousands of volts, it will lead to the burnout of the signal wires on the base substrate, which will reduce the yield of the product.

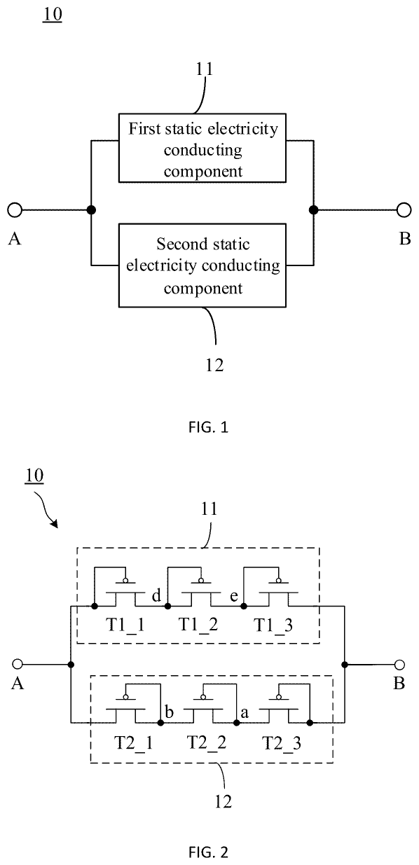

Embodiments of the disclosure provide an electrostatic discharge circuit 10, as shown in FIG. 1, including: a first static electricity conducting component 11 and a second static electricity conducting component 12. The first static electricity conducting component 11 and the second static electricity conducting component 12 each is coupled between a first signal terminal A and a second signal terminal B.

The first static electricity conducting component 11 is configured to: based on that an absolute value of a first voltage difference between the first signal terminal A and the second signal terminal B is less than a first threshold voltage, disconnect the first signal terminal A and the second signal terminal B; and based on that a potential of the first signal terminal A is less than a potential of the second signal terminal B, and an absolute value of a second voltage difference between the first signal terminal A and the second signal terminal B is greater than a second threshold voltage, raise the potential of the first signal terminal A and lower the potential of the second signal terminal B. Here, the second threshold voltage is greater than or equal to the first threshold voltage.

The second static electricity conducting component 12 is configured to: based on that the absolute value of the first voltage difference between the first signal terminal A and the second signal terminal B is less than the first threshold voltage, disconnect the first signal terminal A and the second signal terminal B; and based on that the potential of the first signal terminal A is greater than the potential of the second signal terminal B, and the absolute value of the second voltage difference between the first signal terminal A and the second signal terminal B is greater than the second threshold voltage, lower the potential of the first signal terminal A and raise the potential of the second signal terminal B.

In the electrostatic discharge circuit provided by the embodiments of the disclosure, the first static electricity conducting component and the second static electricity conducting component each is coupled between the first signal terminal and the second signal terminal, allowing to rise the potential of the first signal terminal and lower the potential of the second signal terminal through the first static electricity conducting component based on that the potential of the first signal terminal is less than the potential of the second signal terminal, and the absolute value of the second voltage difference between the first signal terminal and the second signal terminal is greater than the second threshold voltage, and to lower the potential of the first signal terminal and rise the potential of the second signal terminal through the second static electricity conducting component based on that the potential of the first signal terminal is greater than the potential of the second signal terminal, and the absolute value of the second voltage difference between the first signal terminal and the second signal terminal is greater than the second threshold voltage. This allows the static electricity to be conducted between the first signal terminal and the second signal terminal from one to another, realizing electrostatic discharge. Moreover, in the case that the absolute value of the first voltage difference between the first signal terminal and the second signal terminal is less than the first threshold voltage, both the first static electricity conducting component and the second static electricity conducting component can disconnect the first signal terminal and the second signal terminal, at which time the first signal terminal and the second signal terminal can be used to transmit other forms of potential (such as potentials within a specific amplitude range) separately without interfering with each other. Thus, the electrostatic discharge circuit provided by embodiments of the disclosure not only enables static electricity to be conducted between the first signal terminal and the second signal terminal from one to another for electrostatic discharge, but also enables the first signal terminal and the second signal terminal to transmit other forms of potentials, respectively, without interfering with each other.

Exemplarily, a value range of the first threshold voltage may be (ΔV1, ΔV1+ΔV0], here ΔV1 indicates the maximum value of the absolute value of the first voltage difference, and ΔV0 may indicate a preset voltage, such as, for example, ΔV0 may be 1V, 2V, or 3V. Of course, ΔV0 may be determined according to the needs in the actual application, and will not be limited herein.

Exemplarily, the second threshold voltage is greater than or equal to ΔV1+ΔV0. Of course, in practice, the second threshold voltage may be determined according to the needs in the actual application, and is not limited herein.

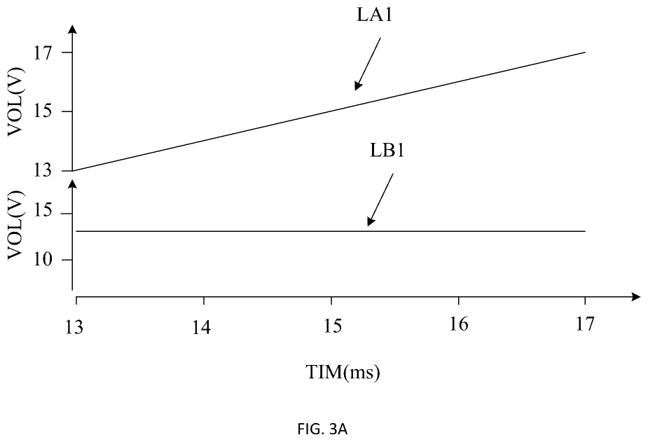

In some embodiments of the disclosure, as shown in FIG. 2, the first static electricity conducting component 11 may include: M first transistors (T1_1˜T1_M, FIG. 2 takes M=3 as an example) connected in series in sequence; among the M first transistors, a second electrode of the first transistor T1_1 at a first position is coupled to the first signal terminal A, a first electrode of the first transistor at a m-th position is coupled to a second electrode of the first transistor at a (m+1)-th position, and a first electrode of the first transistor at the M-th position is coupled to the second signal terminal B; 1≤m≤M, and m and M are integers. Exemplarily, the second electrode of the first transistor T1_1 at the first position is coupled to the first signal terminal A, a first electrode of the first transistor T1_1 at the first position is coupled to a second electrode of the first transistor T1_2 at the second position, a first electrode of the first transistor T1_2 at the second position is coupled to a second electrode of the first transistor T1_3 at the third position, and a first electrode of the first transistor T1_3 at the third position is coupled to the second signal terminal B.

In some embodiments of the disclosure, the second electrode of each of the first transistors T1_1 to T1_3 may be coupled to the gate of each of the first transistors T1_1 to T1_3, respectively, as shown in FIG. 2.

In some embodiments of the disclosure, as shown in FIG. 2, all of the first transistors T1_1 to T1_M in the first static electricity conducting component 11 may be provided as P-type transistors. Optionally, the first electrode of the P-type transistor may be source, and the second electrode of the P-type transistor may be drain. For example, M satisfies the following formula: (M−1)*|Vth1|>ΔV1; here Vth1 indicates a rated threshold voltage of a first transistor, and ΔV1 indicates a maximum value of an absolute value of a first voltage difference. Of course, it is also possible to make the number of first transistors in the first static electricity conducting component 11 greater than M, which is not limited here.

In actual preparation, the threshold voltage of the first transistor may be preset to obtain the first transistor having the preset threshold voltage by, for example, controlling the doping amount of the gate, designing the thickness of the dielectric, selecting the material of the gate, and the like, based on the preset threshold voltage. Then the rated threshold voltage of the first transistor in the embodiments of the disclosure is the preset threshold voltage of the first transistor. Although in the actual preparation process, process factors may cause the threshold voltage of the first transistor actually prepared to not be exactly the same as the preset threshold voltage, and there may be a difference, and the difference may be within an error allowable range. Therefore, the above formula: (M−1)*|Vth1|>ΔV1 is illustrated only in an ideal case, and it can be understood by a person skilled in the art that since the above difference may be a difference within the error allowable range, then the above formula may also be applicable to the case in practical application.

Exemplarily, the electrostatic discharge circuit may be applied to the circuit board to discharge the electrostatic charge that may be generated in the circuit board. In practice, a plurality of lines are provided on the circuit board, and the first signal terminal and the second signal terminal of the electrostatic discharge circuit may be coupled to two adjacent lines, respectively, so that the electrostatic charge in the corresponding line is discharged by the electrostatic discharge circuit. Usually, the lines on the circuit board can transmit electrical signals, such as analog voltage signals, and if a first voltage difference exists between the electrical signals transmitted by the two lines connected with the first signal terminal and the second signal terminal respectively, and the absolute value of the first voltage difference is less than a first threshold voltage, both the first static electricity conducting component and the second static electricity conducting component can disconnect the first signal terminal and the second signal terminal, and the two signal lines coupled to the same electrostatic discharge circuit can be disconnected from each other to avoid mutual interference. It can be understood that the amplitude of the electrical signals transmitted in various lines are not unchanged, i.e., the first voltage difference has a plurality of different values, and therefore, ΔV1 in the disclosure may be the one with the largest absolute value among the first voltage differences having different values. For example, if the absolute value of the amplitude of the analog voltage transmitted in the line ranges from 10V to 25V, the value of the first voltage difference ranges from −15V to 15V, ΔV1 may be 15V, and the first threshold voltage may be 16V.

In the case where the first transistors are all provided as P-type transistors, the number M of the first transistors provided in the first static electricity conducting component may be determined based on the rated threshold voltage of the first transistors and the absolute value of the first voltage difference. Exemplarily, Table 1 shows the relationship between the minimum value of M and ΔV1 when Vth1=−1.5V, and Table 2 shows the relationship between the minimum value of M and ΔV1 when Vth1=−2.5V.

TABLE 1

| | The minimum |
|---|---|
| ΔV1 | value of M |
| 4 V | 4 |
| 6 V | 5 |
| 8 V | 6 |
| 10 V | 8 |

TABLE 2

| | The minimum |
|---|---|
| ΔV1 | value of M |
| 4 V | 3 |
| 6 V | 4 |
| 8 V | 5 |
| 10 V | 6 |

In some embodiments of the disclosure, as shown in FIG. 2, the second static electricity conducting component 12 may include: N second transistors (T2_1 to T2_N, FIG. 2 takes N=3 as an example) sequentially connected in series; among the N second transistors, a first electrode of the second transistor T2_1 at the first position is coupled to the first signal terminal A, a second electrode of the second transistor at the n-th position is coupled to a first electrode of the second transistor at the (n+1)-th position, and a second electrode of the second transistor at the N-th position is coupled to the first signal terminal B; here 1≤n≤N and n and N are integers. Exemplarily, the first electrode of the second transistor T2_1 at the first position is coupled to the first signal terminal A, the second electrode of the second transistor T2_1 at the first position is coupled to the first electrode of the second transistor T2_2 at the second position, the second electrode of the second transistor T2_2 at the second position is coupled to the first electrode of the second transistor T2_3 at the third position, and the second electrode of the second transistor T2_3 at the third position is coupled to the second signal terminal B.

In some embodiments of the disclosure, the second electrode of each of the second transistors T2_1 to T2_3 may be coupled to the gate of each of the second transistors T2_1 to T2_3, respectively, as shown in FIG. 2.

In some embodiments of the disclosure, as shown in FIG. 2, all of the second transistors T2_1 to T2_N in the second static electricity conducting component 12 may be provided as P-type transistors. Optionally, the first electrode of the P-type transistor may be source, and the second electrode of the P-type transistors may be drain.

Exemplarily, N satisfies the following formula: (N−1)*|Vth2|>ΔV1; Vth2 indicates a rated threshold voltage of a second transistor, and ΔV1 indicates the maximum value of the absolute value of the first voltage difference. Of course, it is also possible to make the number of second transistors in the second static electricity conducting component 12 greater than N, without limitation herein.

In actual preparation, the threshold voltage of the second transistor may be preset to obtain the second transistor having the preset threshold voltage by, for example, controlling the doping amount of the gate, designing the thickness of the dielectric, selecting the material of the gate, and the like, based on the preset threshold voltage. Then the rated threshold voltage of the second transistor in the embodiments of the disclosure is the preset threshold voltage of the second transistor. Although in the actual preparation process, process factors may cause the threshold voltage of the second transistor actually prepared to not be exactly the same as the pre-designed threshold voltage, and there may be a difference, the difference may be within an error allowable range. Therefore, the above formula: (N−1)*|Vth2|>ΔV1 is illustrated only in an ideal case, and it is understood by a person skilled in the art that since the above difference may be a difference within the error-permissible range, then the above formula may also be applicable to the case in practical application.

In the case where the second transistors are all provided as P-type transistors, the number N of the second transistors provided in the second static electricity conducting component may be determined based on the rated threshold voltage of the second transistors and the absolute value of the first voltage difference. Exemplarily, Table 3 shows the relationship between the minimum value of N and ΔV1 when Vth2=−1.5V, and Table 4 shows the relationship between the minimum value of N and ΔV1 when Vth2=−2.5V.

TABLE 3

| | The minimum |
|---|---|
| ΔV1 | value of N |
| 4 V | 4 |
| 6 V | 5 |
| 8 V | 6 |
| 10 V | 8 |

TABLE 4

| | The minimum |
|---|---|
| ΔV1 | value of N |
| 4 V | 3 |
| 6 V | 4 |
| 8 V | 5 |
| 10 V | 6 |

As a large amount of static electricity will inevitably be generated during the preparation of the circuit board, the electrostatic discharge circuit can be applied to the circuit board to discharge the static electricity that may be generated in the circuit board, thereby avoiding the lines on the circuit board from burning due to electrostatic breakdown, and improving the yield of the product. In practice, a plurality of lines are provided on the circuit board, and the first signal terminal and the second signal terminal of the electrostatic discharge circuit may be coupled to two adjacent lines, respectively, so that the electrostatic charge in the corresponding lines is discharged through the electrostatic discharge circuit.

Exemplarily, taking the electrostatic discharge circuit 10 shown in FIG. 2 as an example, in the case that neither the first signal terminal A nor the second signal terminal B receives any electrical signal, the potentials of both the first signal terminal A and the second signal terminal B are, for example, V (floating); if the negative electrostatic charge are accumulated or moved to the first signal terminal A, the potential of the first signal terminal A will be less than the potential of the second signal terminal B. When the negative electrostatic charges are accumulated continuously or in large quantities at the first signal terminal A, causing the absolute value of the second voltage difference between the first signal terminal A and the second signal terminal B to be greater than a second threshold voltage, the first static electricity conducting component 11 may cause the negative electrostatic charges to move from the first signal terminal A to the second signal terminal B. For example, when the negative electrostatic charges are accumulated or moved to the first signal terminal A, the first signal terminal A has a negative potential Vesd, at this time, gate voltages of the first transistors T1_1 to T1_3 are Vesd, and source voltages of the first transistors T1_1 to T1_3 are V(floating). Since the absolute value of V(floating) is much smaller than the absolute value of Vesd, the gate-source voltage Vgs=Vesd−V(floating) of any of the first transistors T1_1 to T1_3 is less than Vth1, at this time the first transistors T1_1 to T1_3 are turned on, the negative electrostatic charges move from the first signal terminal A to the second signal terminal B, that is, the current flows from the second signal terminal B to the first signal terminal A, the potential of the first signal terminal A rises, and the negative electrostatic charges are discharged.

Likewise, in the case that neither the first signal terminal A nor the second signal terminal B receives any electrical signal, the potentials of both the first signal terminal A and the second signal terminal B are, for example, V′ (floating); if the positive electrostatic charges are accumulated or moved to the first signal terminal A, the potential of the first signal terminal A will be greater than the potential of the second signal terminal B. When the positive electrostatic charges are accumulated continuously or in large quantities at the first signal terminal A, causing the absolute value of the second voltage difference between the first signal terminal A and the second signal terminal B to be greater than a second threshold voltage, the second static electricity conducting component 12 may cause the positive electrostatic charges to move from the first signal terminal A to the second signal terminal B. For example, when the positive electrostatic charges are accumulated or moved to the first signal terminal A, the first signal terminal A has a positive potential V′esd, the gate voltages of the second transistors T2_1 to T2_3 are V′ (floating), and the source voltages of the second transistors T2_1 to T2_3 are V′esd. Since the absolute value of V′(floating) is much is smaller than the absolute value of V′esd, the gate-source voltage Vgs=V′(floating)−V′esd of any of the second transistors T2_1 to T2_3 is smaller than Vth2, and at this time, the second transistors T2_1 to T2_3 are turned on, and the positive electrostatic charges move from the first signal terminal A to the second signal terminal B, i.e., the current flows from the first signal terminal A to the second signal terminal B, the potential of the first signal terminal A decreases, and the positive electrostatic charges are discharged.

Exemplarily, taking the electrostatic discharge circuit 10 shown in FIG. 2 as an example, in the case that the first signal terminal A and the second signal terminal B each has a potential within a range of a specific amplitude, the absolute value of the specific amplitude, for example, ranges from 10V to 25V, and the absolute value of the first voltage difference between the first signal terminal A and the second signal terminal B is less than a first threshold voltage, both the first static electricity conducting component 11 and the second static electricity conducting component 12 may disconnect the first signal terminal A and the second signal terminal B, ensuring that there is no conducting path between the first signal terminal A and the second signal terminal B. For example, the range of absolute value of the specific amplitude is, such as 10V to 25V, and at this time, if the maximum value ΔV1 of the absolute value of the first voltage difference is 15V, the first threshold voltage may be 16V.

For example, the first threshold voltage is not less than 4V when the maximum value of the absolute value of the first voltage difference is 4 V. For example, the first threshold voltage is 5 V. When each first transistor in the first static electricity conducting component 11 has a Vth1 of −2.5V and each second transistor in the second static electricity conducting component 12 has a Vth2 of −2.5V, the first static electricity conducting component 11 includes three P-type first transistors, and the second static electricity conducting component 12 includes three P-type second transistors. When the potential of the first signal terminal A is 13V and the potential of the second signal terminal B is 17V, since the potential of the first signal terminal A is lower than the potential of the second signal terminal B, for all of the second transistors in the second static electricity conducting component 12, none of them satisfy a turning-on condition, i.e., the second transistors T2_1˜T2_3 are turned off. As for the first static electricity conducting component 11, since the Vth1 of any of the first transistors T1_1 to T1_3 is −2.5V, a critical point at which each of the first transistors T1_1 to T1_3 is turned on and turned off is Vgs=Vth1, and for the first transistor T1_1, according to the formula Vgs−Vth1=VA−Vd−Vth1=0, the VA indicating a voltage at the first signal terminal A and Vd indicating a voltage at node d, it is calculated that Vd=15.5V. Likewise, for the first transistor T1_2, according to the formula Vgs−Vth1=Vd−Ve−Vth=15.5−Ve−(−2.5)=0, Ve indicating a voltage at node e, it is calculated that Ve=18V, and since the voltage at the second signal terminal B is 17V, for the first transistor T1_3, Vgs=Ve−VB=1>Vth1, at which time the first transistor T1_3 is turned off. In this way, a conducting path cannot be established via the first static electricity conducting component 11, avoiding the interference between the potential of the second signal terminal B and the potential of the first signal terminal A.

Likewise, when the potential of the first signal terminal A is 17V and the potential of the second signal terminal B is 13V, the potential of the second signal terminal B and the potential of the first signal terminal A will not interact with each other, which will not be repeated herein.

Exemplarily, in conjunction with Tables 1-4, for example, when ΔV1 is 4V, if Vth1 is −1.5V, at least four P-type transistors are required for each of the first static electricity conducting component 11 and the second static electricity conducting component 12, to ensure that at least one of the P-type transistors is turned off, so that a total of at least eight P-type transistors are required for the first static electricity conducting component 11 and the second static electricity conducting component 12. When Vth1 is −2.5V and ΔV1 is 6V, the first static electricity conducting component 11 and the second static electricity conducting component 12 each requires at least four P-type transistors, to ensure that at least one of the P-type transistors is turned off, so that a total of at least eight P-type transistors are also required for the first static electricity conducting component 11 and the second static electricity conducting component 12.

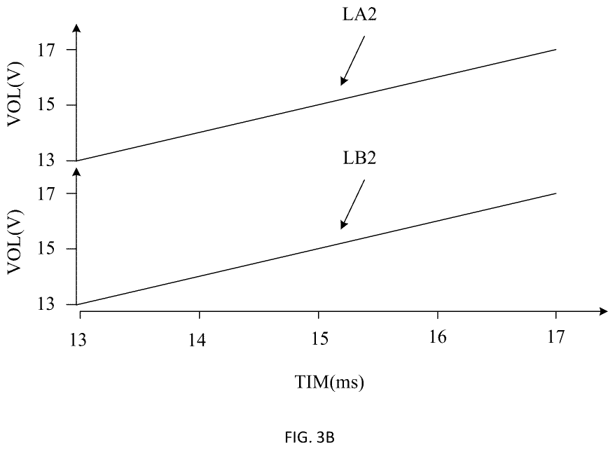

The circuit structure shown in FIG. 2 is used as an example for simulation in the disclosure, and the curve shown in FIG. 3A is obtained. In conjunction with FIG. 3A, LA1 indicates the potential of the first signal terminal A, and LB1 indicates the potential of the second signal terminal B. When the potential LA1 of the first signal terminal A changes linearly from 13V to 17V, and the potential LB1 of the second signal terminal B remains unchanged at 13V, which indicates that the potentials of the first signal terminal A and the second signal terminal B do not interact with each other, and that there is no crosstalk between the two.

The disclosure further provides a simulation of the circuit structure with the first transistor T1_3 and the second transistor T2_3 in FIG. 2 removed as an example, and the curve shown in FIG. 3B is obtained. In conjunction with FIG. 3B, LA2 indicates the potential of the first signal terminal A, and LB2 indicates the potential of the second signal terminal B. When the potential LA2 of the first signal terminal A changes linearly from 13V to 17V, the voltage LB2 of the second signal terminal B changes along with the voltage LA2 of the first signal terminal A, which indicating that crosstalk between the first signal terminal A and the second signal terminal B occurs.

The disclosure further provides a simulation of the circuit structure with the first transistors T1_3 to T1_2 and the second transistors T2_3 to T2_2 in FIG. 2 removed as an example, and the curve shown in FIG. 3C is obtained. In conjunction with FIG. 3C, LA3 indicates the potential of the first signal terminal A, and LB3 indicates the potential of the second signal terminal B. When the voltage LA3 of the first signal terminal A changes linearly from 13V to 17V, and the voltage LB3 of the second signal terminal B changes in accordance with the voltage LA3 of the first signal terminal A, which indicating that crosstalk between the first signal terminal A and the second signal terminal B occurs.

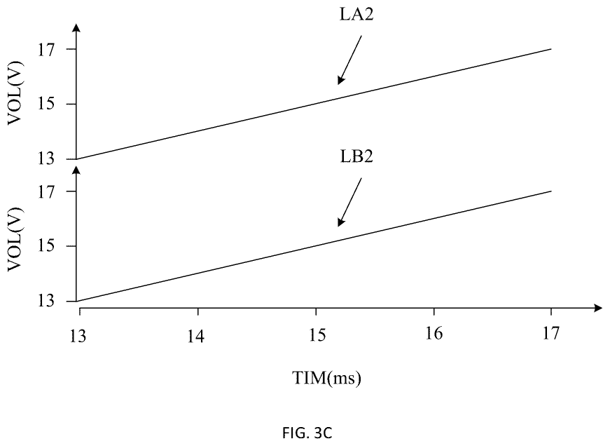

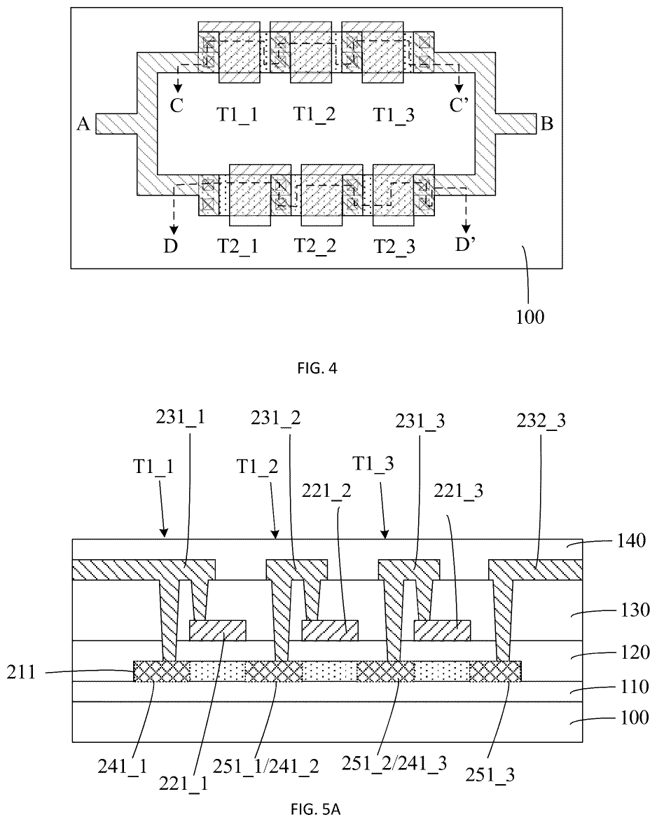

In some embodiments of the disclosure, as shown in FIG. 4 and FIGS. 5A to 5B, the first transistors T1_1 to T1_3 and the second transistors T2_1 to T2_3 are P-type transistors, each of them includes an active layer, a gate, a first electrode and a second electrode. Herein, the active layers 211 of the first transistors T1_1 to T1_3 may be interconnected to form a one-piece structure, and the active layers 212 of the second transistors T2_1 to T2_3 may also be interconnected to form a one-piece structure. The gates 221_1 to 221_3 of the first transistors T1_1 to T1_3 are set at intervals between each other, and the gates 222_1 to 222_3 of the second transistors T2_1 to T2_3 are also set at intervals between each other. Moreover, the active layers 211 include channel regions facing the gates 221_1 to 221_3 of the first transistors T1_1 to T1_3 (i.e., regions in which orthographic projections of the active layers on a plane where the base substrate is located overlap with orthographic projections of the gates on the plane where the base substrate is located), and non-overlapping regions. The non-overlapping regions of the active layers 211 are doped so that the non-overlapping regions are conductive and serve as the second electrodes 241_1 to 241_3 (i.e., the drains) of the first transistors T1_1 to T1_3 and the first electrodes 251_1 to 251_3 (i.e., the sources) of the first transistors T1_1 to T1_3, respectively. Herein, the first electrode 251_1 of the first transistor T1_1 is reused as the second electrode 241_2 of the first transistor T1_2, i.e., the first electrode 251_1 of the first transistor T1_1 is coupled to the second electrode 241_2 of the first transistor T1_2, and the first electrode 251_2 of the first transistor T1_2 is reused as the second electrode 241_3 of the first transistor T1_3, i.e., the first electrode 251_2 of the first transistor T1_2 is coupled to the second electrode 241_3 of the first transistor T1_3.

Further, the active layers 212 include channel regions facing the gates 222_1 to 222_3 of the second transistors T2_1 to T2_3 (i.e., regions in which orthographic projections of the active layers on a plane where the base substrate is located overlap respectively with orthographic projections of the gates on the plane where the base substrate is located), and non-overlapping regions. The non-overlapping regions of the active layers 212 are doped so that the non-overlapping region are conductive and serve as second electrodes 242_1 to 242_3 (i.e., the drains) of the second transistors T2_1 to T2_3 and first electrodes 252_1 to 252_3 (i.e., the sources) of the second transistors T2_1 to T2_3, respectively. Herein, the second electrode 242_1 of the second transistor T2_1 is reused as the first electrode 252_2 of the second transistor T2_2, i.e., the second electrode 242_1 of the second transistor T2_1 is coupled to the first electrode 252_2 of the second transistor T2_2, and the second electrode 242_2 of the second transistor T2_2 is reused as the first electrode 252_3 of the second transistor T2_3, i.e., the second electrode 242_2 of the second transistor T2_2 is coupled to the first electrode 252_3 of the second transistor T2_3.

For example, a buffer layer 110 is provided between the base substrate 100 and the active layer to improve the adhesion of the active layer. There is a gate insulating layer 120 between the active layer and a layer in which the gate is located, an interlayer insulating layer 130 between the layer in which the gate is located and a layer in which a connection portion is located, and a planarization layer 140 on the layer in which the connection portion is located. The connection portions 231_1 to 231_3 are coupled to the active layers 211 through vias passing through the gate insulating layer 120 and the interlayer insulating layer 130, respectively, and the connection portions 231_1 to 231_3 are coupled to the corresponding the gates 221_1 to 221_3 through vias passing through the interlayer insulating layer 130, respectively, so that the gate 221_1 to 221_3 of the first transistors T1_1 to T1_3 are coupled to the second electrodes 241_1 to 241_3 thereof, respectively, to realize the connection in diode mode. In this manner, each of the first transistors T1_1 to T1_3 can operate in the diode mode with unidirectional conduction.

Moreover, the connection portions 232_1 to 232_3 are coupled to the active layer 212 through the vias passing through the gate insulating layer 120 and the interlayer insulating layer 130, respectively, and the connection portions 232_1 to 232_3 are coupled to the corresponding gate electrodes 222_1 to 222_3 through the vias passing through the interlayer insulating layer 130, respectively, so that the gates 222_1 to 222_3 of the second transistors T2_1 to T2_3 222_3 are coupled to the second electrodes 242_1 to 242_3 thereof, respectively, to realize the connection in a diode mode. In this manner, each of the second transistors T2_1 to T2_3 can operate in the diode mode with unidirectional conduction.

Further, the connection portion 231_1 may be directly connected with the first signal terminal A, and the connection portion 231_1 is further coupled to the active layer 212 (e.g., the second electrode 241_1 and the first electrode 252_1) through the vias passing through the gate insulating layer 120 and the interlayer insulating layer 130. The connection portion 232_3 may be directly connected with the second signal terminal B, and the connection portion 232_3 is also coupled to the active layer 211 (e.g., the first electrode 251_3 and the second electrode 242_3) through vias passing through the gate insulating layer 120 and the interlayer insulating layer 130. This can allow a path between the first signal terminal A and the second signal terminal B to transmit static electricity to each other through the first transistors T1_1 to T1_3 and the second transistors T2_1 to T2_3 to be formed.

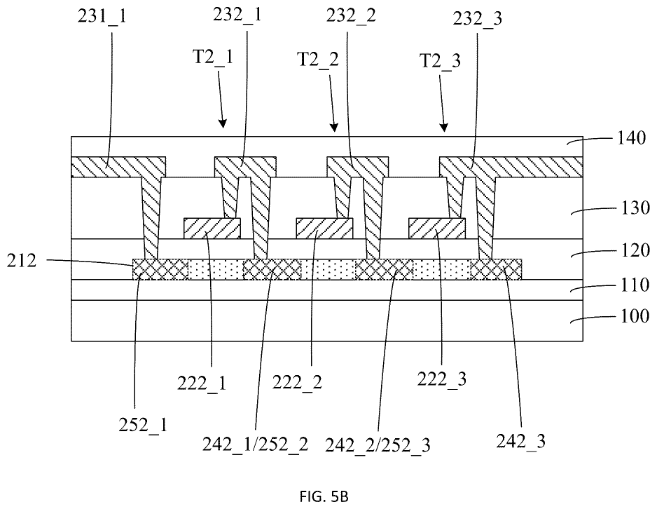

Embodiments of the disclosure provide another schematic structural diagram of the electrostatic discharge circuit, as shown in FIG. 6, which is a variant with respect to the implementations in the above-described embodiments. Only the differences between the present embodiments and the above embodiments are described below, and implementation in common will not be repeated herein.

In some embodiments of the disclosure, it is possible that all first transistors in the first static electricity conducting component 11 are provided as N-type transistors. For example, as shown in FIG. 6, for example, with M=3, the first static electricity conducting component 11 includes first transistors T1_1 to T1_3, and all the first transistors T1_1 to T1_3 are provided as N-type transistors. And, the first electrode and the gate of each of the first transistors T1_1 to T1_3 are coupled with each other.

In some embodiments of the disclosure, it is possible that all second transistors in the second static electricity conducting component 12 are provided as N-type transistors. For example, as shown in FIG. 6, with N=3, for example, the second static electricity conducting component 12 includes second transistors T2_1 to T2_3, and all the second transistors T2_1 to T2_3 are provided as N-type transistors. And, the first electrode and the gate of each of the second transistors T2_1 to T2_3 are coupled with each other.

Optionally, for the N-type transistor, the first electrode may be a drain and the second electrode may be a source.

In the case that the first transistors are all provided as N-type transistors, the number M of the first transistors provided in the first static electricity conducting component may be determined based on the rated threshold voltage of the first transistors and the absolute value of the first voltage difference. Exemplarily, taking Vth1=1.5V, Vth1=2V, and Vth1=2.5V as examples respectively, Table 5 shows the relationship between the minimum value of M and ΔV1 when Vth1=−1.5V, and Table 6 shows the relationship between the minimum value of M and ΔV1 when Vth1=2.5V. The relationship between the minimum value of M and ΔV1 when Vth1=2V can also be shown in Table 6. That is, when Vth1=2V and Vth1=2.5V, both the relationships between the minimum value of M and ΔV1 can follow the relationship shown in Table 6.

TABLE 5

| | The minimum |
|---|---|
| ΔV1 | value of M |
| 4 V | 4 |
| 6 V | 5 |
| 8 V | 6 |
| 10 V | 8 |

TABLE 6

| | The minimum |
|---|---|
| ΔV1 | value of M |
| 4 V | 3 |
| 6 V | 4 |
| 8 V | 5 |
| 10 V | 6 |

In the case that the second transistors are all provided as N-type transistors, the number N of the second transistors provided in the second static electricity conducting component may be determined based on the rated threshold voltage of the second transistors and the absolute value of the first voltage difference. Exemplarily, taking Vth2=1.5V, Vth2=2V, and Vth2=2.5V as examples respectively, Table 7 shows the relationship between the minimum value of N and ΔV1 when Vth2=1.5V, and Table 8 shows the relationship between the minimum value of N and ΔV1 when Vth2=2.5V. The relationship between the minimum value of N and ΔV1 when Vth2=2V can also be shown in Table 8. That is, when Vth2=2V and Vth2=2.5V, both the relationships between the minimum value of N and ΔV1 can follow the relationship shown in

TABLE 7

| | The minimum |
|---|---|
| ΔV1 | value of N |
| 4 V | 4 |
| 6 V | 5 |
| 8 V | 6 |
| 10 V | 8 |

TABLE 8

| | The minimum |
|---|---|
| ΔV1 | value of N |
| 4 V | 3 |
| 6 V | 4 |
| 8 V | 5 |
| 10 V | 6 |

Exemplarily, taking the electrostatic discharge circuit 10 shown in FIG. 6 as an example, in the case that neither the first signal terminal A nor the second signal terminal B receives any electrical signal, the potentials of the first signal terminal A and the second signal terminal B are, for example, both V (floating); if the negative electrostatic charges are accumulated or moved to the first signal terminal A, this causes the potential of the first signal terminal A to be less than the potential of the second signal terminal B. When the negative electrostatic charges are accumulated continuously or in large quantities at the first signal terminal A so that the absolute value of the second voltage difference between the first signal terminal A and the second signal terminal B is greater than a second threshold voltage, the first static electricity conducting component 11 may cause the positively and negative electrostatic charges to move from the first signal terminal A to the second signal terminal B. For example, when the negative electrostatic charges are accumulated or moved to the first signal terminal A, the first signal terminal A has a negative potential Vesd, at which time the gate voltages of the first transistors T1_1 to T1_3 are V(floating) and the source voltages of the first transistors T1_1 to T1_3 are Vesd. Since the absolute value of V(floating) is much smaller than the absolute value of Vesd, the gate-source voltage Vgs=V(floating)−Vesd of any of the first transistors T1_1 to T1_3 is greater than Vth1, at this time the first transistors T1_1 to T1_3 are turned on, the negative electrostatic charges move from the first signal terminal A to the second signal terminal B, that is, the current flows from the second signal terminal B to the first signal terminal A, the potential of the first signal terminal A rises, and the negative electrostatic charges are discharged.

Likewise, in the case that neither the first signal terminal A nor the second signal terminal B receives any electrical signal, the potentials of both the first signal terminal A and the second signal terminal B are, for example, V′ (floating); if the positive electrostatic charges are accumulated or moved to the first signal terminal A, the potential of the first signal terminal A will be greater than the potential of the second signal terminal B. When the positive electrostatic charges are accumulated continuously or in large quantities at the first signal terminal A such that the absolute value of the second voltage difference between the first signal terminal A and the second signal terminal B is greater than a second threshold voltage, the second static electricity conducting component 12 may cause the positive electrostatic charges to move from the first signal terminal A to the second signal terminal B. For example, when the positive electrostatic charges are accumulated or moved to the first signal terminal A, the first signal terminal A has a positive potential V′esd, the gate voltages of the second transistors T2_1 to T2_3 are V′esd, and the source voltages of the second transistors T2_1 to T2_3 are V′(floating). Since the absolute value of V′(floating) is much smaller than the absolute value of V′esd, then the gate-source voltage Vgs=V′esd−V′(floating) of any of second transistors T2_1 to T2_3 is greater than Vth2, and at this time, the second transistors T2_1 to T2_3 are turned on, and the positive electrostatic charges move from the first signal terminal A to the second signal terminal B, i.e., the current flows from the first signal terminal A to the second signal terminal B, the potential of the first signal terminal A decreases, and the positive electrostatic charges are discharged.

Exemplarily, taking the electrostatic discharge circuit 10 shown in FIG. 6 as an example, in the case that the first signal terminal A and the second signal terminal B each has a potential in a range of a specific amplitude, a range of the absolute value of the specific amplitude is, for example, from 10V to 25V, and the absolute value of the first voltage difference between the first signal terminal A and the second signal terminal B is less than a first threshold voltage, both the first static electricity conducting component 11 and the second static electricity conducting component 12 may disconnect the first signal terminal A and the second signal terminal B, ensuring that there is no conducting path between the first signal terminal A and the second signal terminal B. For example, the range of absolute value of the specific amplitude is, for example, from 10V to 25V, at this time, if the maximum value ΔV1 of the absolute value of the first voltage difference is 15V, the first threshold voltage may be 16V.

For example, the first threshold voltage is not less than 4V when the maximum value of the absolute value of the first voltage difference is 4 V. For example, the first threshold voltage is 5 V. When each of the first transistors included in the first static electricity conducting component 11 has a Vth1 of 2.5V, and each of the second transistors included in the second static electricity conducting component 12 has a Vth2 of 2.5V, the first static electricity conducting component 11 includes three N-type first transistors, the second static electricity conducting component 12 includes three N-type second transistors. When the potential of the first signal terminal A is 13V and the potential of the second signal terminal B is 17V, since the potential of the first signal terminal A is higher than the potential of the second signal terminal B, for all the second transistors in the second static electricity conducting component 12, none of them satisfy the turning-on condition, i.e., the second transistors T2_1 to T2_3 are turned off. As for the first static electricity conducting component 11, since the Vth1 of any of the first transistors T1_1 to T1_3 is 2.5V, a critical point at which each of the first transistors T1_1 to T1_3 is turned on and turned off is Vgs=Vth1, and for the first transistor T1_1, according to the formula Vgs−Vth1=VB−Vf−Vth1=0, VB indicating the second signal terminal B voltage and Vf indicating the voltage at point f, it is calculated that Vf=15 V. Likewise, it is calculated that the voltage Vd at node d is 13V, i.e., the voltage at node d is the same as the voltage at the first signal terminal A. For the first transistor T1_1, Vgs=Ve−VA=0<Vth1, at which time the first transistor T1_1 is turned off. In this way, a conducting path via the first static electricity conducting component 11 cannot be established, to avoid the interaction between the potential of the second signal terminal B and the potential of the first signal terminal A. Likewise, when the potential of the first signal terminal A is 17V and the potential of the second signal terminal B is 13V, the potential of the second signal terminal B and the potential of the first signal terminal A will not interact with each other, which will not be repeated herein.

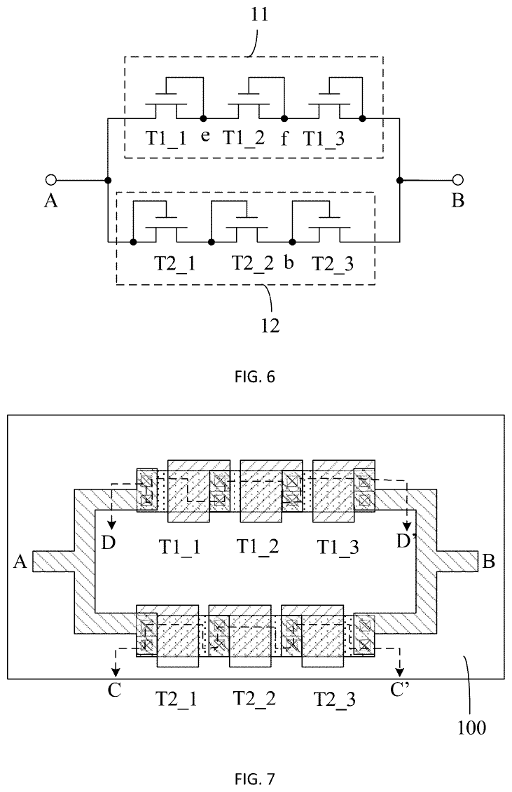

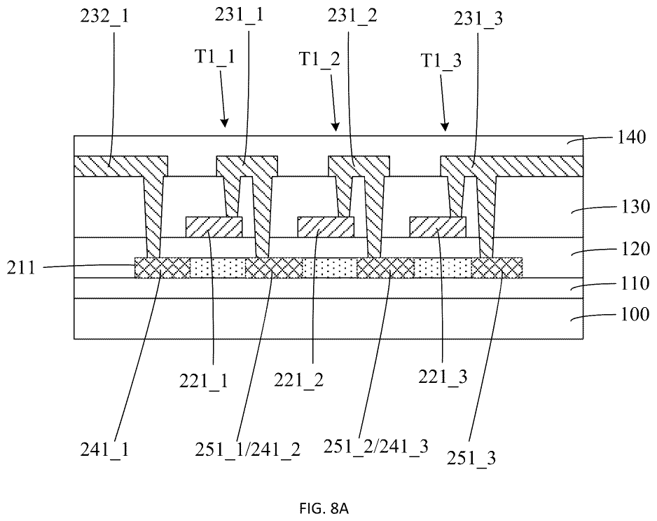

In some embodiments of the disclosure, as shown in FIG. 7 and FIGS. 8A-8B, where the first transistors T1_1 to T1_3 and the second transistors T2_1 to T2_3 are N-type transistors, each of them includes an active layer, a gate, a first electrode and a second electrode, respectively. Herein, the active layers 211 of the first transistors T1_1 to T1_3 may be interconnected to form a one-piece structure, and the active layers 212 of the second transistors T2_1 to T2_3 may also be interconnected to form a one-piece structure. The gates 221_1 to 221_3 of the first transistors T1_1 to T1_3 are set at intervals between each other, and the gates 222_1 to 222_3 of the second transistors T2_1 to T2_3 are also set at intervals between each other.

Further, the active layers 211 include channel regions facing the gates 221_1 to 221_3 of the first transistors T1_1 to T1_3 (i.e., regions in which orthographic projections of the active layers on the plane where the base substrate is located overlap respectively with orthographic projections of the gates on the plane where the base substrate is located), and non-overlapping regions. The non-overlapping regions of the active layers 211 are doped so that the non-overlapping regions are conductive and serve as the second electrodes 241_1 to 241_3 (i.e., the sources) of the first transistors T1_1 to T1_3 and the first electrodes 251_1 to 251_3 (i.e., the drains) of the first transistors T1_1 to T1_3, respectively. Herein, the first electrode 251_1 of the first transistor T1_1 is reused as the second electrode 241_2 of the first transistor T1_2, i.e., the first electrode 251_1 of the first transistor T1_1 is coupled to the second electrode 241_2 of the first transistor T1_2; and the first electrode 251_2 of the first transistor T1_2 is reused as the second electrode 241_3 of the first transistor T1_3, i.e., the first electrode 251_2 of the first transistor T1_2 is coupled to the second electrode 241_3 of the first transistor T1_3.

Further, the active layers 212 include channel regions corresponding to the gates 222_1 to 222_3 of the second transistors T2_1 to T2_3 (i.e., regions in which orthographic projections of the active layers on the plane in which the base substrate is located overlap respectively with orthographic projections of the gates on the plane in which the base substrate is located), and non-overlapping regions. The non-overlapping regions of the active layers 212 are doped so that the non-overlapping regions are conductive and serve as the second electrodes 242_1 to 242_3 (i.e., the sources) of the second transistors T2_1 to T2_3 and the first electrodes 252_1 to 252_3 (i.e., the drains) of the second transistors T2_1 to T2_3, respectively. Herein, the second electrode 242_1 of the second transistor T2_1 is reused as the first electrode 252_2 of the second transistor T2_2, i.e., the second electrode 242_1 of the second transistor T2_1 is coupled to the first electrode 252_2 of the second transistor T2_2; and the second electrode 242_2 of the second transistor T2_2 is reused as the first electrode 252_3 of the second transistor T2_3, i.e., the second electrode 242_2 of the second transistor T2_2 is coupled to the first electrode 252_3 of the second transistor T2_3.

For example, a buffer layer 110 is provided between the base substrate 100 and the active layer to improve the adhesion of the active layer. There is a gate insulating layer 120 between the active layer and a layer in which the gate is located, an interlayer insulating layer 130 between the layer in which the gate is located and a layer in which the connection portion is located, and a planarization layer 140 on the layer in which the connection portion is located. The connection portions 231_1 to 231_3 are coupled to the active layers 211 through vias passing through the gate insulating layer 120 and the interlayer insulating layer 130, respectively, and the connection portions 231_1 to 231_3 are coupled to the corresponding the gates 221_1 to 221_3 through vias passing through the interlayer insulating layer 130, so that the gates 221_1 to 221_3 of the first transistors T1_1 to T1_3 are coupled to the first electrodes 251_1 to 251_3 thereof, respectively, to realize the connection in diode mode. In this manner, each of the first transistors T1_1 to T1_3 can operate in the diode mode with unidirectional conduction.

Moreover, the connection portions 232_1 to 232_3 are coupled to the active layers 212 through vias passing through the gate insulating layer 120 and the interlayer insulating layer 130, respectively, and the connection portions 232_1 to 232_3 are coupled to the corresponding gates 222_1 to 222_3 through vias passing through the interlayer insulating layer 130, respectively, so that the gates 222_1 to 222_3 of the second transistors T2_1 to T2_3 with the first electrodes 252_1 to 252_3 thereof, respectively, to realize the connection in a diode mode. In this manner, each of the second transistors T2_1 to T2_3 can operate in the diode mode with unidirectional conduction.

Further, the connection portion 232_1 may be directly connected with the first signal terminal A, and the connection portion 232_1 is further coupled to the active layer 212 (e.g., the second electrode 241_1 and the first electrode 252_1) through the vias passing through the gate insulating layer 120 and the interlayer insulating layer 130. The connection portion 231_3 may be directly connected with the second signal terminal B, and the connection portion 231_3 is also coupled to the active layer 211 (e.g., the second electrode 242_3 and the first electrode 251_3) through the vias passing through the gate insulating layer 120 and the interlayer insulating layer 130. This allows a path between the first signal terminal A and the second signal terminal B to transmit static electricity to each other through the first transistors T1_1 to T1_3 and the second transistors T2_1 to T2_3 to be formed.

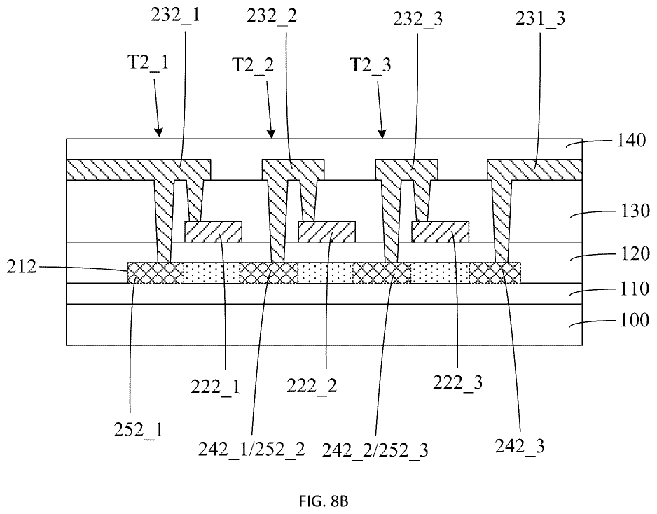

Embodiments of the disclosure also provide an array substrate, as shown in FIGS. 9-11, which may include: a base substrate 100, a plurality of pixels disposed on the base substrate 100, a plurality of signal lines X disposed on the base substrate 100, and a plurality of electrostatic discharge circuits 10 provided by embodiments of the disclosure disposed on the base substrate 100. Herein, any one of the plurality of electrostatic discharge circuits 10 has a first signal terminal A coupled to one of the plurality of signal lines X, and a second signal terminal B coupled to another one of the plurality of signal lines X; and the two signal lines X coupled to the same electrostatic discharge circuit 10 are arranged adjacent to each other. In this way, when the array substrate is subjected to electrostatic discharge, the electrostatic discharge circuit 10 can be used to connect the adjacent signal lines to transmit static electricity between the adjacent signal lines, so as to realize electrostatic discharge. During the normal display of the array substrate, the adjacent signal lines can be disconnected by the electrostatic discharge circuit 10 to transmit a voltage for display on the signal lines, avoiding mutual interference between the signal lines.

Exemplarily, at least one electrostatic discharge circuit 10 is provided between every two adjacent signal lines X. For example, one electrostatic discharge circuit 10 is provided between every two adjacent signal lines X.

Exemplarily, the base substrate 100 has a display region and a peripheral region, the plurality of pixels and the plurality of signal lines are located in the display region, and the plurality of electrostatic discharge circuits 10 are located in the peripheral region. Herein, the plurality of pixels may include red pixels, green pixels, and blue pixels so that color mixing can be performed by red, green, and blue to achieve a color display. Alternatively, the plurality of pixels may include red pixels, green pixels, blue pixels, and white pixels, such that color mixing can be performed by red, green, blue, and white to achieve a color display. Of course, in practice, the light-emitting color of the pixels may be designed and determined according to the actual application environment, and is not limited herein.

Exemplarily, at least one of the plurality of pixels may include a pixel circuit and a light-emitting device coupled to the pixel circuit. Optionally, each pixel of the plurality of pixels may include a pixel circuit and a light-emitting device coupled to the pixel circuit. For example, the pixel circuit may include a plurality of transistors such as a driver transistor, and a switching transistor prepared and formed using a thin film transistor (TFT) preparation process, and a storage capacitor, on the base substrate 100. The specific structure and operating principle of which may be the same as those in the related art and will not be repeated herein.

Exemplarily, the gate of the transistor in the electrostatic discharge circuit 10 may be prepared using the same mask as the gate of the transistor in the pixel circuit.

Exemplarily, the active layer of the transistor in the electrostatic discharge circuit 10 may be prepared using the same mask as the active layer of the transistor in the pixel circuit.

Exemplarily, the first electrode and the second electrode of the transistor in the electrostatic discharge circuit 10 may be prepared using the same mask as the first electrode and the second electrode of the transistor in the pixel circuit.

Exemplarily, the light-emitting device may be, for example, a mini light-emitting diode (Mini LED) or a micro light-emitting diode (Micro LED). Exemplarily, an orthographic projection of the light-emitting device on the base substrate may be quadrilateral, and the sizes of its long side or wide side may take values between 80 μm and 350 μm. The light-emitting device may be set on the base substrate by surface mount technology (SMT) or mass transfer technology.

Exemplarily, a pixel circuit of at least one of the plurality of pixels may be coupled to at least one of the plurality of signal lines to input a signal to the pixel circuit. For example, pixel circuits in one column of pixels may be coupled to one signal line X.

Exemplarily, the plurality of signal lines X extends along the column direction of the pixels, as shown in FIGS. 9-11. Optionally, the base substrate has Q*K pixels, herein, Q indicates the number of rows of pixels and K indicates the number of columns of pixels. In practice, the specific values of Q and K may be determined according to the needs of the actual application and are not limited herein.

Further, the signal lines may include data signal lines, and the pixel circuits in one column of pixels may be coupled to at least one data signal line among the plurality of signal lines. For example, the pixel circuits in one column of pixels may be coupled to one data signal line, so that a total of K data signal lines may be provided on the base substrate 100, which are i.e., the data signal lines DA_1 to DA_k. Further, the first voltage difference may be a voltage difference between a data voltage corresponding to the maximum grayscale and a data voltage corresponding to the minimum grayscale loaded on the data signal line. Taking 256 grayscales as an example, the data voltage corresponding to the maximum grayscale may be the data voltage corresponding to the grayscale of 255, and the data voltage corresponding to the minimum grayscale may be the data voltage corresponding to the grayscale of 0.

Exemplarily, as shown in FIGS. 9-11, one electrostatic discharge circuit 10 may be provided between every two adjacent data signal lines. e.g., one electrostatic discharge circuit 10 is provided between the data signal line DA_1 and the data signal line DA_2, one electrostatic discharge circuit 10 is provided between the data signal line DA_2 and the data signal line DA_3, and . . . one electrostatic discharge circuit 10 is provided between the data signal line DA_ₖ and the data signal line DA_ₖ₊₁, . . . one electrostatic discharge circuit 10 is provided between the data signal line DA_ₖ₋₁ and the data signal line DA_ₖ.

Exemplarily, the peripheral region further includes: at least one electrostatic transmission line 420 and at least one ground terminal 410; at least one end of the at least one electrostatic transmission line 420 is coupled to at least one of the at least one ground terminal 410. The at least one electrostatic transmission line 420 is coupled to at least one of the plurality of signal lines X via at least one of the plurality of electrostatic discharge circuits 10. Optionally, as shown in FIGS. 9-11, the peripheral region further includes one electrostatic transmission line 420 and one ground terminal 410, an end of the electrostatic transmission line 420 is coupled to the ground terminal 410, and the end of the electrostatic transmission line 420 coupled to the ground terminal 410 is also coupled to the leftmost signal line X of the plurality of signal lines via one electrostatic discharge circuit 10, and the other end of the electrostatic transmission line 420 is coupled to the rightmost signal line X of the plurality of signal lines via one electrostatic discharge circuit 10.

Of course, there can be 2, 3, 4 or more electrostatic transmission lines 420, which is not limited herein.

Of course, there can be 2, 3, 4 or more ground terminals 410, which is not limited herein.

Optionally, the ground terminal may be a silver paste dot or a metal terminal, which is not limited herein.

Exemplarily, each of the at least one electrostatic transmission line 420 is provided surrounding the plurality of pixels. This allows the electrostatic transmission lines 420 to be disposed around the edges of the base substrate 100, further blocking the effects of static electricity. Optionally, as shown in FIG. 9, the base substrate 100 is provided with one electrostatic transmission line 420 that extends along the edge of the base substrate 100.

Exemplarily, the peripheral region further includes: a plurality of signal transmission terminals 430 at first ends of the plurality of signal lines; the first end of each of the plurality of signal lines is coupled to at least one of the plurality of signal transmission terminals 430. The at least one ground terminal 410 is disposed at at least one side of the plurality of signal transmission terminals 430, and the at least one electrostatic transmission line 420 extends from a side of the plurality of signal transmission terminals 430 to the other side of the plurality of signal transmission terminals 430. Optionally, as shown in FIG. 9, the first end of one signal line is correspondingly coupled to one signal transmission terminal 430, and, the ground terminal 410 is located at the leftmost side of all of the signal transmission terminals 430. Of course, the ground terminal 410 may also be located at the rightmost side of all the signal transmission terminals 430, which is not limited herein.

Optionally, the signal transmission terminal may be a conductive pad provided separately from the signal line, or may be a portion of the signal line disposed at the end, which is not limited herein.

Exemplarily, as shown in FIGS. 9-11, the peripheral region may include a bonding region BG, and the signal transmission terminals 430, the ground terminals 410, and the electrostatic discharge circuits 10 all are located within the bonding region BG.

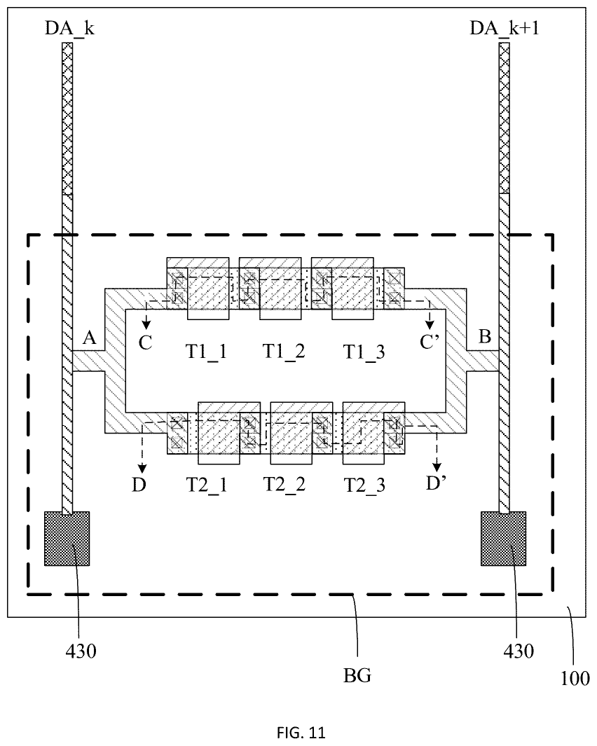

Exemplarily, as shown in FIG. 9 and FIG. 11, the plurality of electrostatic discharge circuits 10 are disposed between a region where the plurality of signal transmission terminals 430 are located and a region where the plurality of signal lines X are located.

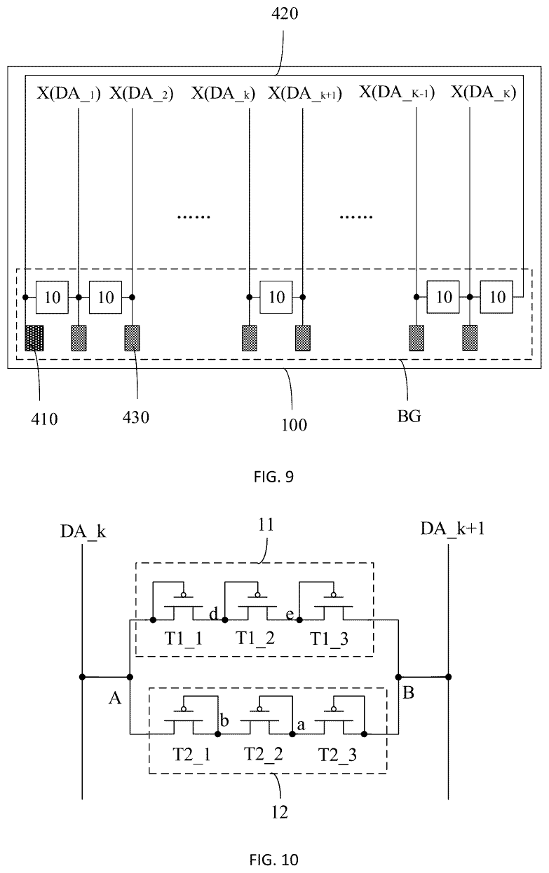

Exemplarily, taking the example that all first transistors T1_1 to T1_3 in the first static electricity conducting component 11 of the electrostatic discharge circuit 10 are provided as P-type transistors, and all second transistors T2_1 to T2_3 in the second static electricity conducting component 12 of the electrostatic discharge circuit 10 are provided as P-type transistors, as shown in FIG. 10 and FIG. 11, the first transistors T1_1 to T1_3 and second transistors T2_1 to T2_3 are provided between the data signal lines DA_ₖ and DA_ₖ₊₁.

Exemplarily, taking the structures shown in FIGS. 9-10 as an example, in the case that neither the data signal line DA_ₖ nor data signal line DA_ₖ₊₁ receives any electrical signal, if the negative electrostatic charges move into the data signal line DA_ₖ, a potential of the data signal line DA_ₖ will be less than a potential of the data signal line DA_ₖ₊₁. When the negative electrostatic charges are accumulated at the data signal line DA_ₖ continuously or in large quantities, causing the absolute value of the second voltage difference between the data signal lines DA_ₖ and DA_ₖ₊₁ to be greater than the second threshold voltage, the first static electricity conducting component 11 may move the positive and negative electrostatic charges from the data signal line DA_ₖ to the data signal line DA_ₖ₊₁.

For example, when the negative electrostatic charges move into the data signal line DA_ₖ, the data signal line DA_ₖ has a negative potential Vesd_da, the gate voltages of the first transistors T1_1 to T1_3 are Vesd_da, and the source voltages of the first transistors T1_1 to T1_3 are V(floating)_da, and since the absolute value of V(floating) is much smaller than the absolute value of Vesd, then the gate-source voltage Vgs=Vesd_da−V(floating)_da of any first transistors T1_1 to T1_3 is less than Vth1, at this time, the first transistors T1_1 to T1_3 are turned on, and the negative electrostatic charges move from the data signal line DA_ₖ to the data signal line DA_ₖ₊₁, i.e., the current flows from the data signal line DA_ₖ₊₁ to the data signal line DA_ₖ, the potential of data signal line DA_ₖ rises, and the negative electrostatic charges are discharged. By analogy, when positive electrostatic charges move into one of the data signal lines, they can be conducted to an adjacent data signal line through the electrostatic discharge circuit, and ultimately to the electrostatic transmission line at the periphery, and then the static electricity is discharged through the ground terminal.

Likewise, in the case that neither the data signal line DA_ₖ nor the data signal line DA_ₖ₊₁ receives any electrical signals, if the positive electrostatic charges move into the data signal line DA_ₖ, the potential of the data signal line DA_ₖ is greater than the potential of the data signal line DA_ₖ₊₁, and when the positive electrostatic charges are accumulated continuously or in large quantities in the data signal line DA_ₖ, causing the absolute value of the second voltage difference between the data signal line DA_ₖ and the data signal line DA_ₖ₊₁ to be greater than the second threshold voltage, the second static electricity conducting component 12 may cause the positive electrostatic charges to move from the data signal line DA_ₖ to the data signal line DA_ₖ₊₁.

For example, when the positive electrostatic charges move into the data signal line DA_ₖ, the data signal line DA_ₖ has a positive potential V′esd_da, the gate voltages of the second transistors T2_1 to T2_3 are V′(floating)_da, the source voltages of the second transistors T2_1 to T2_3 are V′esd_da, and since the absolute value of V′(floating)_da is much smaller than the absolute value of V′esd_da, the gate-source voltage Vgs=V′(floating)_da−V′esd_da of any of second transistors T2_1 to T2_3 is less than Vth2, at which time the second transistors T2_1 to T2_3 are turned on, the positive electrostatic charges move from the data signal line DA_ₖ to the data signal line DA_ₖ₊₁, i.e., the current flows from the data signal line DA_ₖ to the data signal line DA_ₖ₊₁, and the potential of the data signal line DA_ₖ decreases, and the positive electrostatic charges are discharged. By analogy, when negative electrostatic charges move into one of the data signal lines, it can be conducted to an adjacent data signal line through the electrostatic discharge circuit, and ultimately to the electrostatic transmission line at the periphery, and then the static electricity is discharged through the ground terminal.

Exemplarily, taking the structure shown in FIGS. 9-10 as an example, when the data signal line DA_ₖ and the data signal line DA_ₖ₊₁ are transmitting a data voltage, and the absolute value of the first voltage difference between the data signal line DA_ₖ and the data signal line DA_ₖ₊₁ is less than the first threshold voltage, the first static electricity conducting component 11 and the second static electricity conducting component 12 can both disconnect the data signal line DA_ₖ and the data signal line DA_ₖ₊₁, ensuring that there is no conducting path between the data signal line DA_ₖ and the data signal line DA_ₖ₊₁. For example, if an absolute value of an amplitude of a data voltage loaded on the data signal line DA_ₖ and the data signal line DA_ₖ₊₁ ranges from 10V to 25V, and the maximum value ΔV1 of the absolute value of the first voltage difference is 15V, the maximum value of the absolute value of the first voltage difference between the data signal line DA_ₖ and the data signal line DA_ₖ₊₁ may be 15V, and the first threshold voltage may be 16V.

For example, when the maximum value ΔV1 of the absolute value of the first voltage difference is 4V, the first threshold voltage is 5V, then the first static electricity conducting component 11 includes three first transistors, then the second static electricity conducting component 12 includes three second transistors; when the data signal line DA_ₖ transmits a voltage of 13V, and the data signal line DA_ₖ₊₁ transmits a voltage of 17V, since the potential of the data signal line DA_ₖ is lower than the potential of the data signal line DA_ₖ₊₁, for all of the second transistors in the second static electricity conducting component 12, none of them satisfy the turning-on condition, i.e., all of the second transistors T2_1 to T2_3 are turned off. As for the first static electricity conducting component 11, if the Vth1 of any of the first transistors T1_1 to T1_3 is-2.5V, the critical point at which each of the first transistors T1_1 to T1_3 is turned on and turned off is Vgs=Vth1, and for the first transistor T1_1, according to the formula Vgs−Vth1=VA−Vd−Vth1=0, VA indicating the voltage at the first signal terminal A and Vd indicating the voltage at node d, it is calculated that Vd=15.5V, and likewise, for the first transistor T1_2, according to the formula Vgs−Vth1=Vd−Ve−Vth=15.5−Ve−(−2.5)=0, where Ve indicates the voltage at node e, it is calculated that Ve=18V, and since the voltage at the second signal terminal B is 17V, for the first transistor T1_3, Vgs=Ve−VB=1>Vth1, at which time the first transistor T1_3 is turned off. In this way, a conducting path via the first static electricity conducting component 11 cannot be formed, to avoid the interaction between the potential of the data signal line DA_ₖ₊₁ and the potential of the data signal line DA_k. Likewise, when the voltage transmitted by the data signal line DA_ₖ is 17V and the voltage transmitted by the data signal line DA_ₖ₊₁ is 13V, the potential of the data signal line DA_ₖ₊₁ and the potential of the data signal line DA_ₖ will not interact with each other, which will not be repeated herein.

It can be understood that all the first transistors in the first static electricity conducting component are transistors of the same type, and all the second transistors in the second static electricity conducting component are transistors of the same type. The type of all the first transistors in the first static electricity conducting component may be different from the type of all the second transistors in the second static electricity conducting component, or may be the same as the type of all the second transistors in the second static electricity conducting component, which is not limited in the disclosure.

It is understood that the electrostatic discharge circuit provided in the embodiments of the disclosure is provided between any two adjacent data signal lines, or the electrostatic discharge circuit provided in the embodiments of the disclosure is provided between at least two data signal lines, and is not limited herein.

Embodiments of the disclosure also provide a display apparatus including a plurality of the aforementioned array substrate provided by embodiments of the disclosure spliced together. The display apparatus solves the problem in a similar principle as the aforementioned array substrate, so the implementation of the display apparatus can refer to the implementation of the aforementioned array substrate, and the repetition will not be repeated herein.

In specific implementation, in the embodiments of the disclosure, a plurality of array substrates may be spliced together using seamless splicing to form the above-described display apparatus provided by the embodiments of the disclosure.

In specific implementation, in the disclosure embodiments, the display apparatus may be: a cell phone, a tablet computer, a television, a monitor, a laptop computer, a digital photo frame, a navigator, and any other product or component having a display function. Other essential components of the display apparatus are understood by those of ordinary skill in the art, and are not described herein, nor should they be used as a limitation of the disclosure.

In the electrostatic discharge circuit, the array substrate, and the display apparatus provided by embodiments of the disclosure, by providing a first static electricity conducting component and a second static electricity conducting component each coupled between the first signal terminal and the second signal terminal, when the potential of the first signal terminal is less than the potential of the second signal terminal and the absolute value of the second voltage difference between the first signal terminal and the second signal terminal is greater than a second threshold voltage, the voltage of the second signal terminal can be transmitted to the first signal terminal through the first static electricity conducting component. Further, when the potential of the first signal terminal is greater than the potential of the second signal terminal and the absolute value of the second voltage difference between the first signal terminal and the second signal terminal is greater than the second threshold voltage, the voltage at the first signal terminal is transmitted to the second signal terminal through the second static electricity conducting component. This allows the static electricity to be conducted between the first signal terminal and the second signal terminal from one to another, realizing electrostatic discharge. Moreover, when the absolute value of the first voltage difference between the first signal terminal and the second signal terminal is less than the first threshold voltage, both the first static electricity conducting component and the second static electricity conducting component can disconnect the first signal terminal and the second signal terminal, at which time it is possible to enable the first signal terminal and the second signal terminal to transmit other forms of voltage respectively without interfering with each other. Therefore, the electrostatic discharge circuit provided by embodiments of the disclosure can not only cause static electricity to be conducted between the first signal terminal and the second signal terminal from one to another to realize electrostatic discharge, but can also cause the first signal terminal and the second signal terminal to transmit other forms of voltage, respectively, without interfering with each other.

Although preferred embodiments of the disclosure have been described, additional changes and modifications may be made to these embodiments once the basic inventive concepts are known to one of skill in the art. Therefore, the appended claims are intended to be construed to include the preferred embodiments as well as all changes and modifications that fall within the scope of the disclosure.

Obviously, those skilled in the art can make various changes and modifications to the embodiments of the disclosure without departing from the spirit and scope of the embodiments of the disclosure. In this way, if these modifications and variations of the embodiments of the disclosure fall within the scope of the claims of the disclosure and equivalent technologies, the disclosure is also intended to include these modifications and variations.

1. An electrostatic discharge circuit, comprising:
a first static electricity conducting component, coupled between a first signal terminal and a second signal terminal; wherein the first static electricity conducting component is configured to: based on that an absolute value of a first voltage difference between the first signal terminal and the second signal terminal is less than a first threshold voltage, disconnect the first signal terminal from the second signal terminal; and
based on that a potential of the first signal terminal is less than a potential of the second signal terminal, and an absolute value of a second voltage difference between the first signal terminal and the second signal terminal is greater than a second threshold voltage, rise the potential of the first signal terminal and lower the potential of the second signal terminal; wherein the second threshold voltage is greater than or equal to the first threshold voltage; and
a second static electricity conducting component, coupled between the first signal terminal and the second signal terminal, wherein the second static electricity conducting component is configured to:
based on that the absolute value of the first voltage difference between the first signal terminal and the second signal terminal is less than the first threshold voltage, disconnect the first signal terminal from the second signal terminal; and
based on that the potential of the first signal terminal is greater than the potential of the second signal terminal, and the absolute value of the second voltage difference between the first signal terminal and the second signal terminal is greater than the second threshold voltage, lower the potential of the first signal terminal and rise the potential of the second signal terminal.

2. The electrostatic discharge circuit according to claim 1, wherein the first static electricity conducting component comprises: M first transistors connected in series in sequence;
wherein in the M first transistors, a second electrode of a first transistor at a first position is coupled to the first signal terminal, a first electrode of a first transistor at an m-th position is coupled to a second electrode of a first transistor at an (m+1)-th position, and a first electrode of a first transistor at a M-th position is coupled to the second signal terminal; wherein 1≤m≤M, and m and M are integers.

3. The electrostatic discharge circuit according to claim 2, wherein
all first transistors in the first static electricity conducting component are P-type transistors, and a second electrode and a gate of the first transistor are coupled to each other; and
M satisfies a following formula:
$$( M - 1 ) * \vert V th 1 \vert > ΔV1 ;$$
wherein Vth1 indicates a rated threshold voltage of the first transistor, and ΔV1 indicates a maximum value of the absolute value of the first voltage difference.

4. The electrostatic discharge circuit according to claim 2, wherein
all first transistors in the first static electricity conducting component are N-type transistors, and a first electrode and a gate of the first transistor are coupled to each other; and
M satisfies a following formula:
$$( M - 1 ) * \vert V th 1 \vert > ΔV1 ;$$
wherein Vth1 indicates a rated threshold voltage of one first transistor, and ΔV1 indicates a maximum value of the absolute value of the first voltage difference.

5. The electrostatic discharge circuit according to claim 1, wherein the second static electricity conducting component comprises: N second transistors connected in series in sequence;
wherein in the N second transistors, a first electrode of a second transistor at a first position is coupled to the first signal terminal, a second electrode of a second transistor at a n-th position is coupled to a first electrode of a second transistor at a (n+1)-th position, a second electrode of a second transistor at a N-th position is coupled to the second signal terminal; wherein 1≤n≤N, and n and N are integers.

6. The electrostatic discharge circuit according to claim 5, wherein
all second transistors in the second static electricity conducting component are P-type transistors, and a second electrode and a gate of the second transistor are coupled to each other; and
N satisfies a following formula:
$$( N - 1 ) * \vert V th 2 \vert > ΔV1 ;$$
wherein Vth2 indicates a rated threshold voltage of the second transistor, and ΔV1 indicates a maximum value of the absolute value of the first voltage difference.

7. The electrostatic discharge circuit according to claim 5, wherein
all second transistors in the second static electricity conducting component are N-type transistors, and a first electrode and a gate of the second transistor are coupled to each other; and
N satisfies a following formula:
$$( N - 1 ) * \vert V th 2 \vert > ΔV1 ;$$
wherein Vth2 indicates a rated threshold voltage of one second transistor and, ΔV1 indicates a maximum value of the absolute value of the first voltage difference.

8. An array substrate, comprising:
a base substrate;
a plurality of pixels on the base substrate; wherein at least one of the plurality of pixels comprises a pixel circuit;
a plurality of signal lines on the base substrate; wherein the pixel circuit of the at least one of the plurality of pixels is coupled to at least one of the plurality of signal lines; and
a plurality of electrostatic discharge circuits according to claim 1 on the base substrate;
wherein a first signal terminal of any one of the plurality of electrostatic discharge circuits is coupled to one of the plurality of signal lines, and a second signal terminal of the any one of the plurality of electrostatic discharge circuits is coupled to another one of the plurality of signal lines; and
two signal lines connected with a same electrostatic discharge circuit are arranged adjacent to each other.

9. The array substrate according to claim 8, wherein the array substrate comprises a display region and a peripheral region; wherein
the plurality of pixels and the plurality of signal lines are located in the display region; and
the plurality of electrostatic discharge circuits are located in the peripheral region.

10. The array substrate according to claim 9, wherein the peripheral region further comprises: at least one electrostatic transmission line and at least one ground terminal;
wherein at least one end of the at least one electrostatic transmission line is coupled to at least one of the at least one ground terminal; and
the at least one electrostatic transmission line is coupled to at least one of the plurality of signal lines via at least one of the plurality of electrostatic discharge circuits.

11. The array substrate according to claim 10, wherein the at least one electrostatic transmission line is arranged around the plurality of pixels.

12. The array substrate according to claim 9,
wherein the peripheral region further comprises: a plurality of signal transmission terminals located at first ends of the plurality of signal lines;
wherein the first end of each of the plurality of signal lines is coupled to at least one of the plurality of signal transmission terminals; and
the at least one ground terminal is located at at least one side of the plurality of signal transmission terminals, and the at least one electrostatic transmission line extends from a side of the plurality of signal transmission terminals to the other side of the plurality of signal transmission terminals.

13. The array substrate according to claim 12, wherein the plurality of electrostatic discharge circuits are located between a region where the plurality of signal transmission terminals are located and a region where the plurality of signal lines are located.

14. The array substrate according to claim 8,
wherein the signal lines comprise data signal lines; wherein
pixel circuits in one column of pixels are coupled to at least one data signal line of the plurality of signal lines; and
the first voltage difference is a voltage difference between a data voltage corresponding to a maximum grayscale and a data voltage corresponding to a minimum grayscale loaded on the data signal line.

15. A display apparatus, comprising a plurality of array substrates according to claim 8, wherein the plurality of array substrates are spliced together.
